(19) United States
(12) Patent Application Publication
(10) Pub. No.: US 2009/0246717 A1
(43) Pub. Date: Oct. 1, 2009

(54) METHOD FOR FORMING A PATTERNED PHOTORESIST LAYER

(75) Inventors: Meng-Chi Huang, Fongshan City (TW); Cheng-Hsuan Lin, Taoyuan City (TW); Fuh-Yu Chang, Jhubei City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, Hsinchu (TW)

(21) Appl. No.: 12/187,334

(22) Filed: Aug. 6, 2008

(30) Foreign Application Priority Data
Mar. 26, 2008 (TW) 97110709

(51) Int. Cl. G03F 7/20

(52) U.S. Cl. 430/326; 430/325

(57) ABSTRACT

A photoresist layer is disclosed. Utilizing light diffraction properties, a transparent layer is disposed between a light-shielding layer and a photoresist layer during an exposure step, such that the patterned photoresist layer has non-vertical sidewalls. The method of the invention can be applied during front side exposure or back side exposure, and is also practical for positive type photoresists or negative photoresists.

### CROSS REFERENCE TO RELATED APPLICATIONS

This Application claims priority of Taiwan Patent Application No. 097110709, filed on Mar. 26, 2008, the entirety of which is incorporated by reference herein.

### BACKGROUND OF THE INVENTION

1. Field of the Invention

The present invention relates to a lithography process, and in particular relates to a lithography process for forming structures with non-vertical sidewalls.

2. Description of the Related Art

In a micro-electro-mechanical process, bulk micromachining, ICP dry etching, gray-level masks, ultra precision machining, and the likes, are usually applied to manufacture tilt structures, however, the described processes, machines or materials have the following limitations. First, while bulk micromachining can form specific angles by utilizing the lattice of silicon wafers and specific solutions, degree of angles cannot be changed. Next, both the ICP dry etching process and gray-level masks substantially increase fabrication costs. Additionally, ultra precision machining is difficult and increases fabrication time and costs as various lathes and cutting heads are required to manufacture different structures by precision and form non-continuous structures.

Accordingly, a novel method for manufacturing tilt microstructures is called for.

### BRIEF SUMMARY OF THE INVENTION

The invention provides a method for forming a patterned photoresist layer, comprising providing a substrate having a top surface and a bottom surface, forming a photoresist layer on the top surface of the substrate, providing a transparent layer on the photoresist layer, providing a light-shielding layer on the transparent layer, providing an exposure source for exposing the photoresist layer through the light-shielding layer and the transparent layer, and developing the photoresist layer to form a patterned photoresist layer, wherein the patterned photoresist layer and the substrate have a non-vertical contact angle.

The invention also provides another method for forming a patterned photoresist layer, comprising providing a transparent substrate having a top surface and a bottom surface, forming a photoresist layer on the top surface of the substrate, providing a transparent layer under the bottom surface of the transparent substrate, providing a light-shielding layer under the transparent layer, providing an exposure source for exposing the photoresist layer through the light-shielding layer, the transparent layer, and the transparent substrate, and developing the photoresist layer to form a patterned photoresist layer, wherein the patterned photoresist layer and the substrate have a non-vertical contact angle.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1-5 are cross sections showing a lithography process utilizing front side exposure accompanying a positive type photoresist in one embodiment of the invention;

FIGS. 6-7 are cross sections showing a lithography process utilizing front side exposure accompanying a negative type photoresist in one embodiment of the invention;

FIGS. 8-12 are cross sections showing a lithography process utilizing back side exposure accompanying a positive type photoresist in one embodiment of the invention; and

FIGS. 13-14 are cross sections showing a lithography process utilizing back side exposure accompanying a negative type photoresist in one embodiment of the invention.

### DETAILED DESCRIPTION OF THE INVENTION

The following description is the best-contemplated mode of carrying out the invention. This description is made for the purpose of illustrating the general principles of the invention and should not be taken in a limiting sense. The scope of the invention is best determined by reference to the appended claims.

While light from an exposure source passes through a light-shielding layer such as openings of a photomask, light intensity is stronger in the opening core and weaker in the opening edge due to diffraction. The invention applies the diffraction principle by interposing a transparent layer between a photoresist material and a light-shielding layer, such that the patterned photoresist layer and the substrate have a non-vertical contact angle.

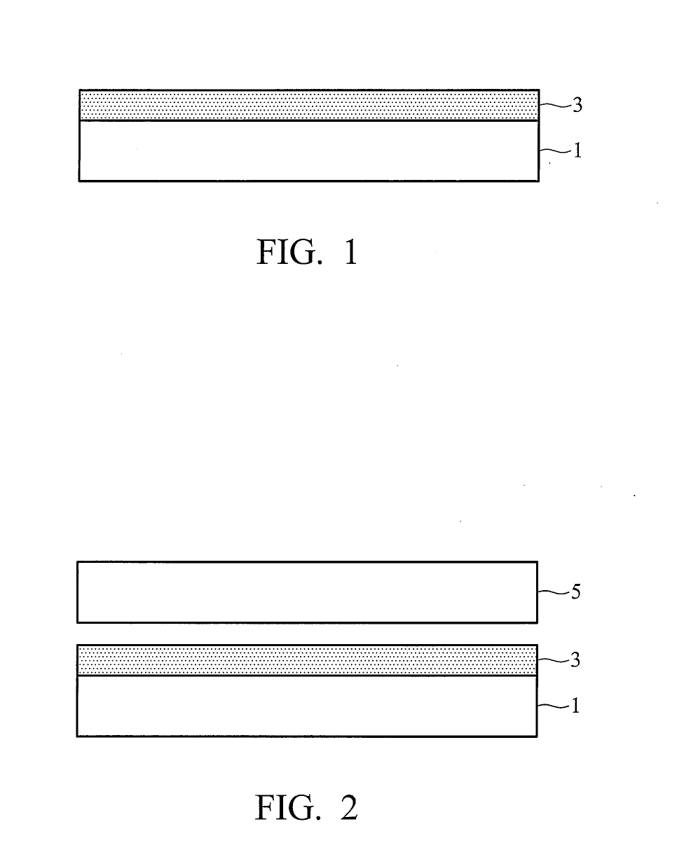

FIGS. 1-5 show a lithography process in one embodiment of the invention. The exposure source and the photoresist layer are located on the same side of the substrate, which is known as frond side exposure. In FIG. 1, first, a substrate 1 is provided. The substrate 1 can be silicon wafer, silicon on insulator (SOI), or the likes. Additionally, the substrate 1 can be glass substrate, flexible plastic substrate, or the likes. The substrate 1 may further include active/passive circuits, devices, or other layouts. The positive type photoresist layer 3 on the top surface of the substrate 1 can be formed by a conventional spin-on method.

Subsequently, in FIG. 2, a transparent layer 5 is formed on the positive type photoresist layer 3. The transparent layer 5 includes inorganic material such as glass or indium tin oxide (ITO), organic material such as polymethylmethacrylate, polycarbonate, or polyethylene terephthalate, organic-inorganic composite material, or combinations thereof. The transparent layer 5 has a thickness of 0.1 mm to 5 mm. The transparent layer 5 and the positive type photoresist layer 3 have a space therebetween, however, the transparent layer 5 can be adjacent to the positive type photoresist layer 3 if the lithography process and the positive type photoresist layer 3 are not influenced.

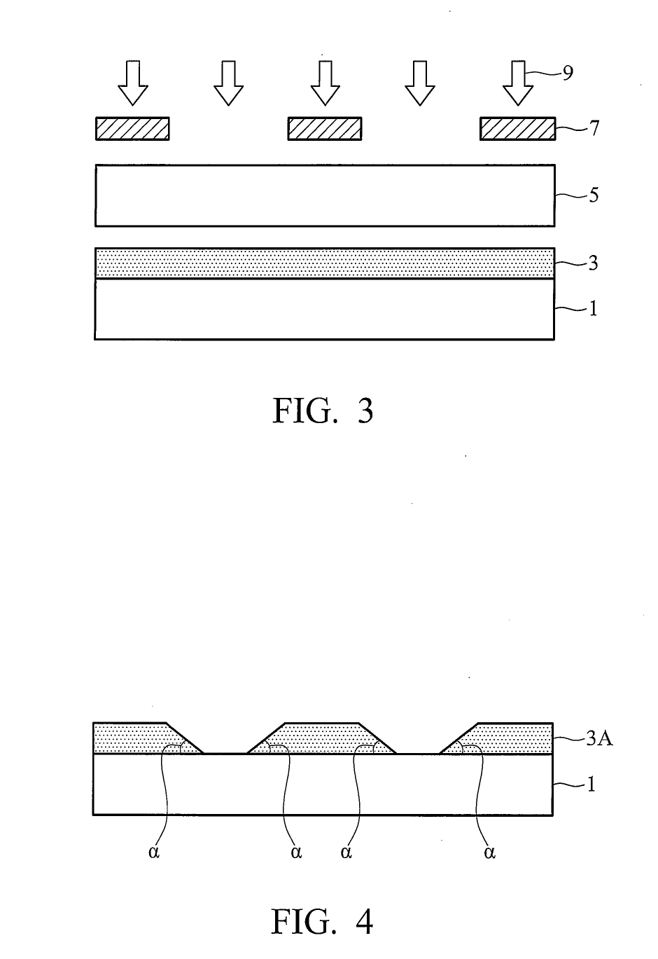

Subsequently, in FIG. 3, a light-shielding layer 7 is provided on the transparent layer 5, and the exposure step is processed by an exposure source 9. The light-shielding layer 7 and the transparent layer 5 have a space therebetween, however, the light-shielding layer 7 can be adjacent to the transparent layer 5 if the lithography process is not influenced. In one embodiment, the light-shielding layer 7 is a conventional photomask. In another embodiment, the light-shielding layer 7 is a light-shielding pattern directly formed on the transparent layer 5. The light from the exposure source 9 passes through the light-shielding layer 7 and the transparent layer 5 to expose the positive type photoresist layer 3. In one embodiment, the exposure source 9 includes an ultraviolet, laser, or X-ray exposure source, and the likes.

Finally, in FIG. 4, the exposed positive type photoresist layer 3 is developed to complete a patterned photoresist layer 3A. The patterned photoresist layer 3A having a narrow top and wide bottom is a so-called “small head structure” patterned photoresist layer 3A. The patterned photoresist layer 3A and the substrate 1 have a contact angle α of less than 90 degrees, and the tilt level of the contact angle α is determined by the absorption of the transparent layer 5. A thicker transparent layer 5 has higher absorption, thereby forming a smaller contact angle α. In one embodiment, the contact angle α is 15 to 85 degrees. In one embodiment, the transparent layer 5 has a thickness of 0.1-1 mm, and the contact angle α is 60 to 85 degrees. In one embodiment, the transparent layer 5 has a thickness of 1-2 mm, and the contact angle α is 45 to 70 degrees. In one embodiment, the transparent layer 5 has a thickness of 2-3 mm, and the contact angle α is 30 to 60 degrees. In one embodiment, the transparent layer 5 has a thickness of 3-4 mm, and the contact angle α is 20 to 50 degrees. In one embodiment, the transparent layer 5 has a thickness of 4-5 mm, and the contact angle α is 15 to 40 degrees.

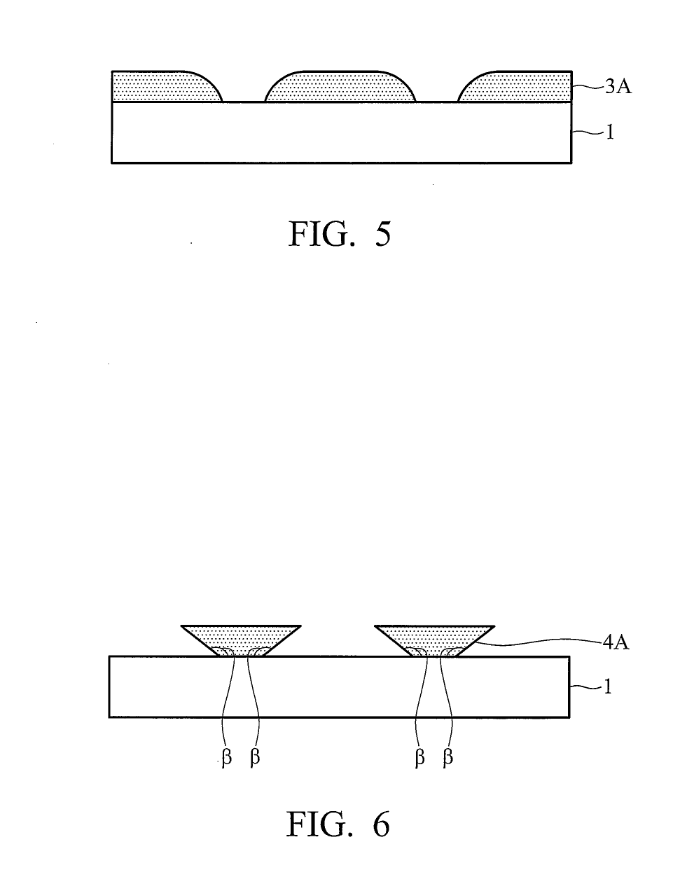

Although the patterned photoresist layer 3A in FIG. 4 has a planar sidewall, it can be curved as shown in FIG. 5. The structural difference between FIGS. 4 and 5 is derived from the material type of the transparent layer 5. The transparent layer 5 for FIG. 4 is an inorganic material such as glass, so the patterned photoresist layer 3A has a planar sidewall 4. On the other hand, for FIG. 5, the patterned photoresist layer 3A has a curved sidewall since the transparent layer 5 is an organic material such as poly(methylmethacrylate). In FIG. 5, the curvature ratio of the patterned photoresist layer 3A sidewall is determined by the absorption of the transparent layer 5. A thicker transparent layer 5 has higher absorption, thereby forming a smaller sidewall slope of the patterned photoresist layer 3A. The patterned photoresist layer 3A can be applied as microlens arrays utilized in optical devices.

Another embodiment is substantially similar to above embodiment, wherein the only difference is that the photoresist layer is a negative type photoresist. Because the processes according to FIGS. 1-3 are similar, the repetitive description is omitted for brevity. In FIG. 6, a patterned photoresist layer 4A is formed from the negative photoresist layer after an exposure and development process. The patterned photoresist layer 4A having a wide top and narrow bottom is a so-called “big head structure” patterned photoresist layer 4A. The patterned photoresist layer 4A and the substrate 1 have a contact angle β greater than 90 degrees, and the tilt level of the contact angle β is determined by the absorption of the transparent layer 5. A thicker transparent layer 5 has higher absorption, thereby forming a greater contact angle β. In one embodiment, the contact angle β is 95 to 165 degrees. In one embodiment, the transparent layer 5 has a thickness of 0.1-1 mm, and the contact angle β is 95 to 115 degrees. In one embodiment, the transparent layer 5 has a thickness of 1-2 mm, and the contact angle β is 110 to 130 degrees. In one embodiment, the transparent layer 5 has a thickness of 2-3 mm, and the contact angle β is 120 to 140 degrees. In one embodiment, the transparent layer 5 has a thickness of 3-4 mm, and the contact angle β is 130 to 150 degrees. In one embodiment, the transparent layer 5 has a thickness of 4-5 mm, and the contact angle α is 140 to 165 degrees.

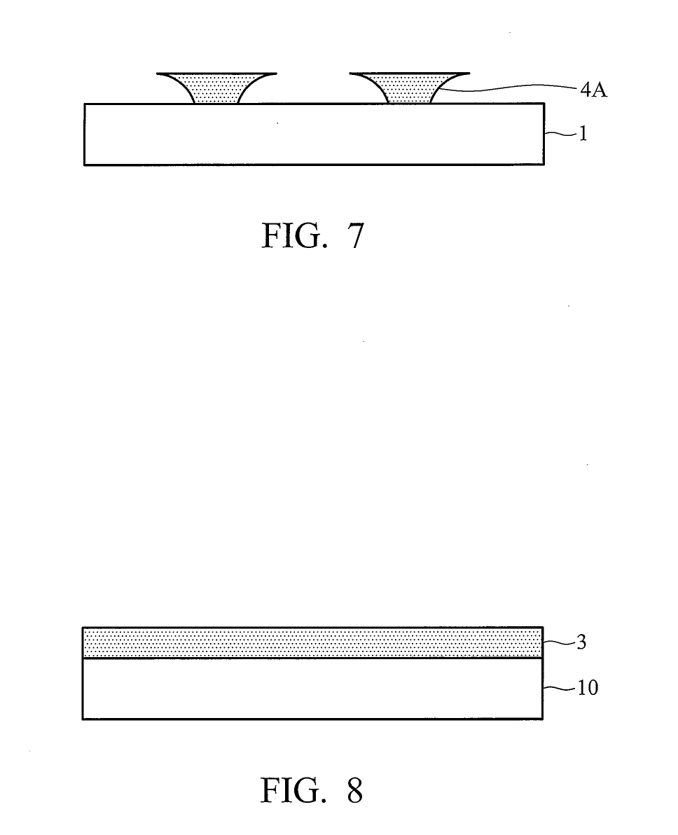

Although the patterned photoresist layer 4A in FIG. 6 has a planar sidewall, it can be curved as shown in FIG. 7. The structural difference between FIGS. 6 and 7 is derived from the material type of the transparent layer 5. In FIG. 6, the transparent layer 5 is an inorganic material such as glass, so the patterned photoresist layer 4A has a planar sidewall. On the other hand, for FIG. 7, the patterned photoresist layer 4A has a curved sidewall since the transparent layer 5 is an organic material such as poly(methylmethacrylate). In FIG. 7, the curvature ratio of the patterned photoresist layer 4A sidewall is determined by the absorption of the transparent layer 5. A thicker transparent layer 5 has higher absorption, thereby forming a smaller sidewall slope of the patterned photoresist layer 4A.

FIGS. 8-12 show a lithography process in a further embodiment of the invention. The exposure source and the photoresist layer are located on the different sides of the transparent substrate, respectively. Because the light from the exposure source passes through the transparent substrate before exposing the photoresist layer, the process is known as back side exposure. In FIG. 8, the transparent substrate 10 can be transparent materials such as glass substrate, flexible plastic substrate, or the likes. The transparent substrate 10 may further include active/passive circuits, devices, or other layouts. The positive type photoresist layer 3 on the top surface of the transparent substrate 10 can be formed by a conventional spin-on method.

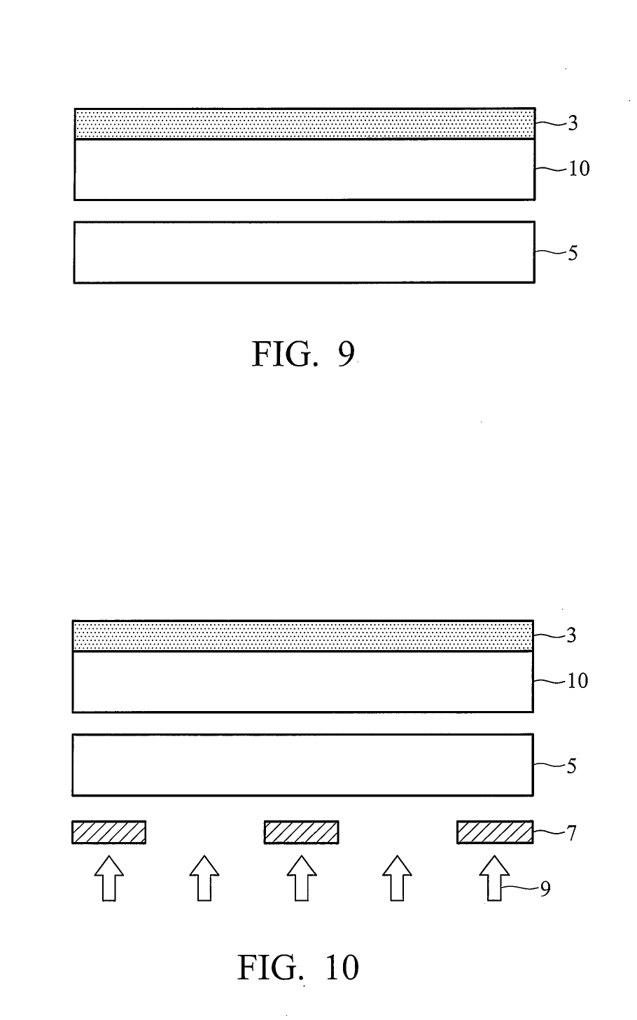

Subsequently, in FIG. 9, a transparent layer 5 is formed under the bottom surface of the transparent substrate 10. The transparent layer 5 includes inorganic material such as glass or indium tin oxide (ITO), organic material such as polymethylmethacrylate, polycarbonate, or polyethylene terephthalate, organic-inorganic composite material, or combinations thereof. The transparent layer 5 has a thickness of 0.1 mm to 5 mm. The transparent layer 5 and the transparent substrate 10 have a space therebetween, however, the transparent layer 5 can be adjacent to the transparent substrate 10 if the lithography process is not influenced.

Subsequently, in FIG. 10, a light-shielding layer 7 is provided under the transparent layer 5, and the exposure step is processed by an exposure source 9. The light-shielding layer 7 and the transparent layer 5 have a space therebetween, however, the light-shielding layer 7 can be adjacent to the transparent layer 5 if the lithography process is not influenced. In one embodiment, the light-shielding layer 7 is a conventional photomask. In another embodiment, the light-shielding layer 7 is a light-shielding pattern directly formed under the transparent layer 5. The light from the exposure source 9 passes through the light-shielding layer 7, the transparent layer 5, and the transparent substrate 10 to expose the positive type photoresist layer 3. In one embodiment, the exposure source 9 includes an ultraviolet, laser, X-ray exposure source, and the likes.

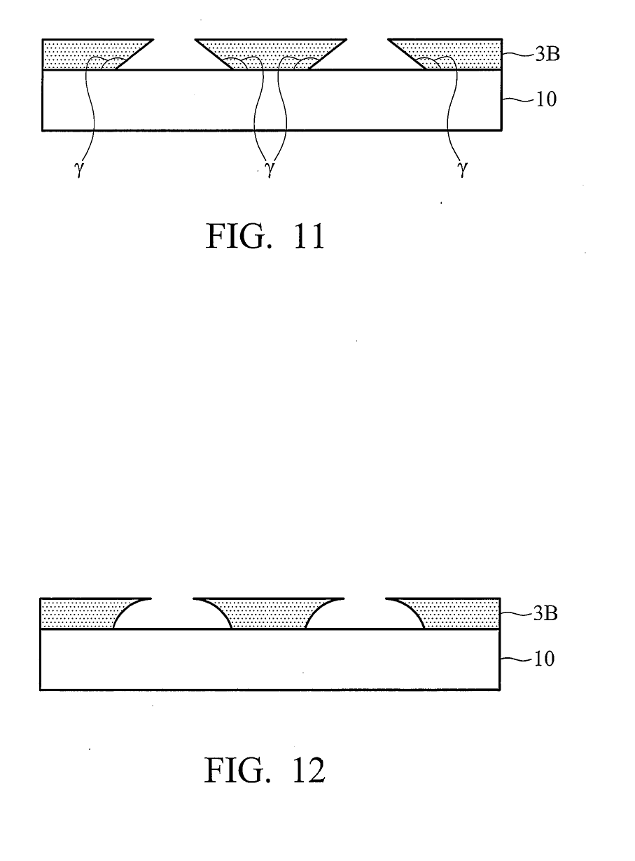

Finally, in FIG. 11, the exposed positive type photoresist layer 3 is developed to complete a patterned photoresist layer 3B. The patterned photoresist layer 3B having wide top and narrow bottom is a so-called “big head structure” patterned photoresist layer 3B. The patterned photoresist layer 3B and the transparent substrate 10 have a contact angle γ greater than 90 degrees, and the tilt level of the contact angle γ is determined by the absorption of the transparent layer 5 and the transparent substrate 10. When the total thickness of the transparent layer 5 and the transparent substrate 10 is thicker, the absorption thereof will be higher, thereby forming a greater contact angle γ. In one embodiment, the contact angle γ is 95 to 165 degrees. In one embodiment, the transparent layer 5 and the transparent substrate have a total thickness of 0.1-1 mm, and the contact angle γ is 95 to 115 degrees. In one embodiment, the transparent layer 5 and the transparent substrate 10 have a total thickness of 1-2 mm, and the contact angle γ is 110 to 130 degrees. In one embodiment, the transparent layer 5 and the transparent substrate 10 have a total thickness of 2-3 mm, and the contact angle γ is 120 to 140 degrees. In one embodiment, the transparent layer 5 and the transparent substrate 10 have a total thickness of 3-4 mm, and the contact angle γ is 130 to 150 degrees. In one embodiment, the transparent layer 5 and the transparent substrate 10 have a total thickness of 4-5 mm, and the contact angle γ is 140 to 165 degrees.

Although the patterned photoresist layer 3B in FIG. 11 has a planar sidewall, it can be curved as shown in FIG. 12. The structural difference between FIGS. 11 and 12 is derived from the material type of the transparent layer 5. For FIG. 11, the transparent layer 5 is an inorganic material such as glass, so the patterned photoresist layer 3B has a planar sidewall. On the other hand, for FIG. 12, the patterned photoresist layer 3B has a curved sidewall since the transparent layer 5 is an organic material such as poly(methylmethacrylate). In FIG. 12, the curvature ratio of the patterned photoresist layer 3B sidewall is determined by the absorption of the transparent layer 5. A thicker transparent layer 5 has higher absorption, thereby forming a smaller sidewall slope of the patterned photoresist layer 3B.

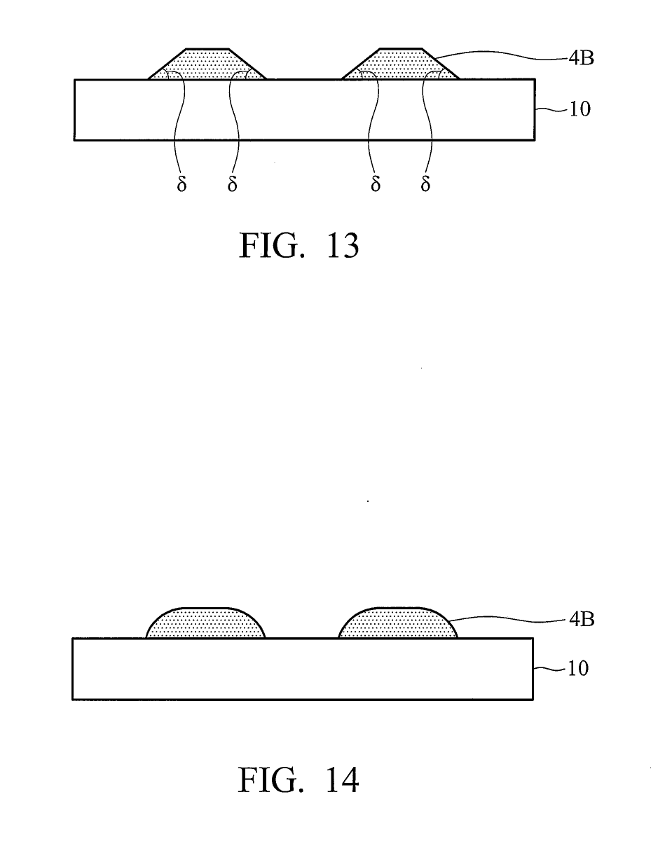

Another embodiment is substantially similar to the above embodiment with the only difference is that the photoresist layer is a negative type photoresist. Because the processes according to FIGS. 8-10 are similar, the repetitive description is omitted for brevity. In FIG. 13, a patterned photoresist layer 4B is formed from the negative photoresist layer after being exposed and developed. The patterned photoresist layer 4B having a narrow top and wide bottom is a so-called “small head structure” patterned photoresist layer 4B. The patterned photoresist layer 4B and the transparent substrate 10 have a contact angle δ of less than 90 degrees, and the tilt level of the contact angle δ is determined by the absorption of the transparent layer 5 and the transparent substrate 10. When the total thickness of the transparent layer 5 and the transparent substrate 10 is thicker, the absorption thereof will be higher, thereby forming a smaller contact angle δ. In one embodiment, the contact angle δ is 15 to 85 degrees. In one embodiment, the transparent layer 5 and the transparent substrate 10 have a total thickness of 0.1-1 mm, and the contact angle δ is 60 to 85 degrees. In one embodiment, the transparent layer 5 and the transparent substrate 10 have a total thickness of 1-2 mm, and the contact angle δ is 45 to 70 degrees. In one embodiment, the transparent layer 5 and the transparent substrate 10 have a total thickness of 2-3 mm, and the contact angle δ is 30 to 60 degrees. In one embodiment, the transparent layer 5 and the transparent substrate 10 have a total thickness of 3-4 mm, and the contact angle δ is 20 to 50 degrees. In one embodiment, the transparent layer 5 and the transparent substrate 10 have a total thickness of 4-5 mm, and the contact angle δ is 15 to 40 degrees.

Although the patterned photoresist layer 4B in FIG. 13 has a planar sidewall, it can be curved as shown in FIG. 14. The structural difference between FIGS. 13 and 14 is derived from the material type of the transparent layer 5. For FIG. 13, the transparent layer 5 is an inorganic material such as glass, so the patterned photoresist layer 4B has a planar sidewall. On the other hand, for FIG. 14, the patterned photoresist layer 4B has a curved sidewall since the transparent layer 5 is an organic material such as poly(methylmethacrylate). In FIG. 14, the curvature ratio of the patterned photoresist layer 4B sidewall is determined by the absorption of the transparent layer 5 and the transparent substrate 10. When the total thickness of the transparent layer 5 and the transparent substrate 10 is thicker, the absorption thereof will be higher, thereby forming a smaller sidewall slope of the patterned photoresist layer 4B.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a patterned photoresist layer, comprising:
providing a substrate having a top surface and a bottom surface;
forming a photoresist layer on the top surface of the substrate;
providing a transparent layer on the photoresist layer;
providing a light-shielding layer on the transparent layer;
providing an exposure source for exposing the photoresist layer through the light-shielding layer and the transparent layer; and
developing the photoresist layer to form a patterned photoresist layer, wherein the patterned photoresist layer and the substrate have a non-vertical contact angle.

2. The method as claimed in claim 1, wherein the non-vertical angle is 15 to 85 degrees or 95 to 165 degrees.

3. The method as claimed in claim 1, wherein the non-vertical angle is a curve.

4. The method as claimed in claim 1, wherein the photoresist layer comprises a positive type photoresist or a negative type photoresist.

5. The method as claimed in claim 1, wherein the light-shielding layer is a photomask.

6. The method as claimed in claim 1, wherein the transparent layer comprises glass, indium tin oxide, polymethylmethacrylate, polycarbonate, polyethylene terephthalate, or combinations thereof.

7. The method as claimed in claim 1, wherein the transparent layer has a thickness of 0.1-1 mm, and the non-vertical angle is 60 to 85 degrees or 95 to 115 degrees.

8. The method as claimed in claim 1, wherein the transparent layer has a thickness of 1-2 mm, and the non-vertical angle is 45 to 70 degrees or 110 to 130 degrees.

9. The method as claimed in claim 1, wherein the transparent layer has a thickness of 2-3 mm, and the non-vertical angle is 30 to 60 degrees or 120 to 140 degrees.

10. The method as claimed in claim 1, wherein the transparent layer has a thickness of 3-4 mm, and the non-vertical angle is 20 to 50 degrees or 130 to 150 degrees.

11. The method as claimed in claim 1, wherein the transparent layer has a thickness of 4-5 mm, and the non-vertical angle is 15 to 40 degrees or 140 to 165 degrees.

12. A method for forming a patterned photoresist layer, comprising:
providing a transparent substrate having a top surface and a bottom surface;
forming a photoresist layer on the top surface of the substrate;
providing a transparent layer under the bottom surface of the transparent substrate;
providing a light-shielding layer under the transparent layer;
providing an exposure source for exposing the photoresist layer through the light-shielding layer, the transparent layer, and the transparent substrate; and
developing the photoresist layer to form a patterned photoresist layer, wherein the patterned photoresist layer and the substrate have a non-vertical contact angle.

13. The method as claimed in claim 12, wherein the non-vertical angle is 15 to 85 degrees or 95 to 165 degrees.

14. The method as claimed in claim 12, wherein the non-vertical angle is a curve.

15. The method as claimed in claim 12, wherein the photoresist layer comprises a positive type photoresist or a negative type photoresist.

16. The method as claimed in claim 12, wherein the light-shielding layer is a photomask.

17. The method as claimed in claim 12, wherein the transparent layer comprises glass, indium tin oxide, polymethylmethacrylate, polycarbonate, polyethylene terephthalate, or combinations thereof.

18. The method as claimed in claim 12, wherein the transparent layer and the transparent substrate have a total thickness of 0.1-1 mm, and the non-vertical angle is 60 to 85 degrees or 95 to 115 degrees.

19. The method as claimed in claim 12, wherein the transparent layer and the transparent substrate have a total thickness of 1-2 mm, and the non-vertical angle is 45 to 70 degrees or 110 to 130 degrees.

20. The method as claimed in claim 12, wherein the transparent layer and the transparent substrate have a total thickness of 2-3 mm, and the non-vertical angle is 30 to 60 degrees or 120 to 140 degrees.

21. The method as claimed in claim 12, wherein the transparent layer and the transparent substrate have a total thickness of 3-4 mm, and the non-vertical angle is 20 to 50 degrees or 130 to 150 degrees.

22. The method as claimed in claim 12, wherein the transparent layer and the transparent substrate have a total thickness of 4-5 mm, and the non-vertical angle is 15 to 40 degrees or 140 to 165 degrees.
